(19) United States
(12) Patent Application Publication
(10) Pub. No.: US 2015/0228848 A1
(43) Pub. Date: Aug. 13, 2015

(54) NITRIDE SEMICONDUCTOR LIGHT-EMITTING ELEMENT AND METHOD FOR PRODUCING SAME

(71) Applicant: USHIO DENKI KABUSHIKI KAISHA, Tokyo (JP)

(72) Inventors: Kohei MIYOSHI, Himeji-shi (JP); Masashi TSUKIHARA, Himeji-shi (JP)

(73) Assignee: USHIO DENKI KABUSHIKI KAISHA, Tokyo (JP)

(21) Appl. No.: 14/617,655

(22) Filed: Feb. 9, 2015

(30) Foreign Application Priority Data
Feb. 12, 2014 (JP) 2014-024535

(51) Int. Cl. H01L 33/00; H01L 33/44

(52) U.S. Cl. CPC H01L 33/0075; H01L 33/44; H01L 2933/0033

(57) ABSTRACT

Provided are a semiconductor light-emitting element having an n-type nitride semiconductor layer capable of suppressing appearance of a crack than before, and a method for producing the same. The method includes a step (a) of forming a GaN layer on a growth substrate; a step (b) of forming a multi-layered film including a first layer of a nitride semiconductor containing In and a second layer formed of a nitride semiconductor on the GaN layer; a step (c) of forming a protective layer formed of a nitride semiconductor on the multi-layered film; and a step (d) of forming an n-type nitride semiconductor layer on the protective layer at a growth temperature higher than that in the step (b) and the step (c), wherein in the step (d), the multi-layered film is thermally decomposed to form an internal void.

### BACKGROUND OF THE INVENTION

1. Field of the Invention

The present invention relates to a nitride semiconductor light-emitting element and a method for producing the same.

2. Description of the Related Art

Nowadays, shortening of the emission wavelength of a semiconductor light-emitting element is advanced. Patent Document 1 below discloses the technique of a semiconductor light-emitting element capable of emitting light with a short wavelength by using AlGaN as a light-emitting layer.

### PRIOR ART DOCUMENT

### Patent Document

[Patent Document 1] Japanese Patent No. 4218597 Non-Patent Document

[Non-patent Document 1] S. R. Lee, et. al, “In situ measurements of the critical thickness for strain relaxation in AlGaN/GaN heterostructures”, December 2004, Applied Physics Letters, Vol. 85, No. 25, 20

### SUMMARY OF THE INVENTION

### Problem to be Solved by the Invention

Nitride semiconductors such as GaN and AlGaN have the wurtzite crystal structure (hexagonal crystal structure). Regarding the plane of the wurtzite crystalline structure, the crystal face and the orientation are represented by a fundamental vector indicated by a1, a2, a3 and c according to the 4 index notation (hexagonal indexing). The fundamental vector c extends in the direction of [0001], and this direction is called “c-axis”. The plane perpendicular to the c-axis is called “c-plane” or “(0001) plane”.

Conventionally, in preparing a semiconductor light-emitting element by using a nitride semiconductor, a substrate having the c-plane substrate as a principal plane is used as a substrate on which the nitride semiconductor crystal is grown. Actually, on this substrate, an undoped GaN layer is grown, and further, an n-type nitride semiconductor layer is grown thereon.

FIG. 9 is a schematic sectional view showing a structure of a conventional semiconductor light-emitting element 90. In the following drawings, the actual dimensional ratio and the depicted dimensional ratio on the drawing do not necessarily coincide with each other.

The semiconductor light-emitting element 90 includes, on a growth substrate 61 configured a sapphire substrate, an undoped GaN layer 36 formed into a thickness of, for example, 3 μm, and an n-type nitride semiconductor layer 95 which is, for example, an n-type AlGaN layer formed on the GaN layer 36 to have a predetermined thickness of less than 1 μm. The semiconductor light-emitting element 90 also includes, on the n-type nitride semiconductor layer 95, an active layer 33 showing a multi-quantum well structure (MQW) in which a light-emitting layer comprising InGaN and a barrier layer comprising AlGaN are repeatedly laminated.

Further, the semiconductor light-emitting element 90 has, on the active layer 33, a p-type nitride semiconductor layer 31 which is, for example, a p-type AlGaN layer formed into a thickness of 150 nm. On the p-type nitride semiconductor layer 31, a p-type contact layer formed of a GaN layer having a p-type impurity concentration higher than that in the p-type nitride semiconductor layer 31 is formed as necessary.

In order to improve the extraction efficiency of light emitted from the active layer 33, it is necessary that the layer on the active layer 33 in which the light extraction surface is formed is configured to have higher band gap energy than the energy of the emitted light. In the semiconductor light-emitting element 90 shown in FIG. 9, when an n-side electrode and a p-side electrode are disposed at a position vertically opposite to each other with the active layer 33 interposed therebetween, an electrode layer which is to be the p-side electrode is formed on the p-type semiconductor layer 31, and a substrate is bonded thereon, and then the GaN layer 36 and the growth substrate 61 are delaminated to locate the n-type nitride semiconductor layer 95 on the upper side and the substrate on the lower side. Thus, the n-side electrode is formed on the n-type nitride semiconductor layer 95. At this time, the side on which the n-side electrode is located serves as the light extraction plane, and the light emitted from the active layer 33 passes inside the n-type nitride semiconductor layer 95 and is extracted outside the semiconductor light-emitting element 90.

From the viewpoint of increasing the light extraction efficiency of the semiconductor light-emitting element 90, preferably, the light emitted from the active layer 33 penetrates the n-type nitride semiconductor layer 95 as much as possible rather than being absorbed in the n-type nitride semiconductor layer 95. In particular, when the light having a wavelength of the near-ultraviolet wavelength region is emitted from the active layer 33, a method of enhancing the band gap energy by raising the Al composition in AlGaN while forming the n-type nitride semiconductor layer 95 with n-type AlGaN is conceivable to increase the light extraction efficiency.

However, as shown in FIG. 9, the n-type nitride semiconductor layer 95 is formed on the GaN layer 36 by epitaxial growth. The lattice constant of AlGaN is smaller than the lattice constant of GaN, and the difference in lattice constant (mismatch) increases as the Al composition increases. As a result, when the n-type nitride semiconductor layer 95 is formed of AlGaN having high Al composition, a tensile stress 81 to the n-type nitride semiconductor layer 95 from the GaN layer 36 increases. The tensile stress 81 increases along with an increase in the thickness of the n-type nitride semiconductor layer 95, and causes deterioration in luminous efficiency due to occurrence of surface roughing, cracking, and misfit dislocation associated with crystal defect when the tensile stress 81 exceeds a certain threshold.

For this reason, the Al composition of the AlGaN layer is restricted by the thickness of the AlGaN layer to be formed. For example, Non-patent document 1 above describes the relationship between the Al composition of the AlGaN layer and the critical thickness, but lacks the disclosure of data of equal to or more than 1 μm, and indicates that the critical thickness of the AlGaN layer falls within the range of several nanometers to several hundred nanometers. The present inventors have experientially ascertained that cracking occurs in the AlGaN layer with a probability of almost 100% when the thickness is made 2 μm in forming the AlGaN layer having an Al composition of 5% by the conventional method.

On the other hand, when the thickness of the n-type nitride semiconductor layer 95 is too small, the current concentratedly flows in the site where the p-side electrode and the n-side electrode are vertically opposite to each other in the active layer 33 upon application of a voltage between the electrodes . As a result, the light-emitting region is reduced, and the luminous efficiency is deteriorated. In addition, since the current flows in a part of the active layer 33, the current locally concentrates to cause non-uniformity of carriers in the active layer 33, and hence high emission intensity cannot be obtained. Also in Patent document 1, the n-type AlGaN layer having a thickness of 0.2 μm is formed as the n-type nitride semiconductor layer 95, and hence the current cannot be sufficiently extended in the direction parallel with the substrate plane in the n-type nitride semiconductor layer 95.

In light of the above problems, an object of the present invention is to provide a semiconductor light-emitting element having an n-type nitride semiconductor layer capable of enhancing the band gap energy and suppressing the occurrence of a crack than before even with a larger thickness, and a method for producing the same.

### Means for Solving the Problem

A method for producing a semiconductor light-emitting element according to the present invention comprises:
a step (a) of forming a GaN layer on a growth substrate formed of a GaN substrate or a sapphire substrate;
a step (b) of forming a multi-layered film including a first layer formed of a nitride semiconductor containing In and a second layer formed of a nitride semiconductor having composition different from that of the first layer on the GaN layer;
a step (c) of forming a protective layer formed of a nitride semiconductor on the multi-layered film;
a step (d) of forming an n-type nitride semiconductor layer at a growth temperature higher than that in the step (b) and the step (c) on the protective layer;
a step (e) of forming an active layer and a p-type nitride semiconductor layer on the n-type nitride semiconductor layer; and
a step (f) of irradiating light having a wavelength of smaller energy than band gap energy of the nitride semiconductor constituting the multi-layered film to delaminate the growth substrate, wherein
in the step (d), the multi-layered film is thermally decomposed to form an internal void.

According to the above method, after forming the protective layer formed of a nitride semiconductor on the multi-layered film, the temperature is elevated, and the n-type nitride semiconductor layer is formed. Since In is taken into crystals only at thermodynamically lower temperature compared with Al or Ga, the first layer containing In can no longer endure as crystals and is thermally decomposed as a result of temperature rise during execution of the step (d), and metal such as In precipitates. As a result, the volume contracts in association with change of the nitride semiconductor from crystal structure to metal structure, and internal voids are formed therein.

If the aforementioned voids are formed in the course of forming the n-type nitride semiconductor layer, it is possible to release the stress caused by lattice mismatch between the GaN layer and the n-type nitride semiconductor layer to the voids. Accordingly, it is possible to make the thickness at which a crack-free n-type nitride semiconductor layer can be formed (critical thickness) larger than before.

In the step (c), the protective layer is formed on the multi-layered film at a temperature lower than that in the step (d). As a result, in the stage where the protective layer is formed, thermal decomposition of the first layer containing In has not occurred, and excellent crystallinity is maintained. Therefore, in forming the n-type nitride semiconductor layer in a high temperature condition in the step (d), it is possible to grow the n-type nitride semiconductor layer with taking over the excellent crystallinity of the protective layer even when the crystallinity is broken due to thermal decomposition of the first layer containing In, and thus it is possible to form the n-type nitride semiconductor layer having excellent crystallinity.

In the step (b), in place of merely forming a layer formed of a nitride semiconductor containing In (first layer), a multi-layered film made of the first layer and a second layer formed of a nitride semiconductor having composition different from that of the first layer is formed. When the first layer formed of a nitride semiconductor layer containing In is singly formed as a thick layer, lattice mismatch between the first layer and the GaN layer formed in the step (a) causes appearance of misfit dislocation in the first layer. This dislocation is taken over to the upper layer in the course of the epitaxial growth, so that it is impossible to achieve excellent crystallinity in the n-type nitride semiconductor layer.

On the other hand, when the thickness of the first layer containing In is extremely small, the volume of voids formed in the step (d) is extremely small, so that there is a possibility that the stress arising in the n-type nitride semiconductor layer cannot sufficiently absorbed. Also, even when light is irradiated in the step (f), the light is not sufficiently absorbed in the layers containing In because such layers are few, so that there is a possibility that the growth substrate cannot be delaminated. In light of this, by constituting the film formed in the step (b) of a multi-layered film made up of a first layer containing In and a second layer having composition different from that of the first layer, and repeating, for example, the first layer plural times, it is possible to ensure the total thickness of the first layer while holding down the dislocation density. Accordingly, it is possible to form a crack-free n-type nitride semiconductor layer in the form of a thick film.

According to the above method, there is a possibility that metal such as In precipitates in the region where the multi-layered film has been formed as a result of thermal decomposition of the multi-layered film in the step (d). In the condition that the layer containing precipitated metal exists, light from the active layer is absorbed by the metal, and the light extraction efficiency is extremely deteriorated. In light of this, by delaminating the growth substrate using the light having a wavelength of smaller energy than the band gap energy of the nitride semiconductor constituting the multi-layered film in the step (f), the layer containing precipitated metal is eliminated together with the growth substrate from the laminate made up of the n-type nitride semiconductor layer, the active layer and the p-type nitride semiconductor layer. Since it is possible to make the light-emitting element formed through the steps (a)-(f) free from a layer containing precipitated metal, the problem that the light is absorbed by the metal as described above does not arise.

After the step (f), the step of completely removing the metal attached to the surface of the protective layer may be executed by washing the surface with acid such as aqua regia.

The multi-layered film can be formed of a multi-layered film of InₓGa₁₋ₓN (0.1≦x≦0.2)/GaN.

By forming the first layer of the multi-layered film with InGaN having an In composition of equal to or more than 10% and equal to or less than 20%, it is possible to form internal voids to such an extent that the stress arising in the n-type nitride semiconductor layer can be absorbed without leading occurrence of misfit dislocation at high density in the first layer.

The n-type nitride semiconductor layer can include n-type AlₙGa₁₋ₙN (0≦n≦1) having a thickness of equal to or more than 2 μm.

As described in the section of “Problem to be Solved by the Invention”, when the AlGaN layer is formed on the GaN layer, tensile stress arises in the AlGaN layer due to the difference in lattice constant, so that there is a problem that a crack-free AlGaN layer cannot be formed in the form of a thick film. However, according to the aforementioned method, since the stress can be absorbed by the voids formed as a result of thermal decomposition of the multi-layered film, it is possible to form a crack-free AlGaN layer even in the form of a very thick film having a thickness of 2 μm or larger. As a result, even in the semiconductor light-emitting element having an active layer that radiates near-ultra violet light, it is possible to extend the current in the direction parallell with the substrate plane within the n-type nitride semiconductor layer, and to improve the light extraction efficiency.

The protective layer may be formed of the same material as that of the n-type nitride semiconductor layer.

When the growth temperature in the step (b) is defined as Tb and the growth temperature in the step (c) is defined as Tc, Tb<Tc<Tb+150(° C.) may be satisfied.

By executing the step (c) in the temperature condition as described above, it is possible to deposit the protective layer in the condition that excellent crystallinity is maintained without causing thermal decomposition of the multi-layered film deposited in the step (b).

The emission wavelength of the active layer may be equal to or more than 362 nm and equal to or less than 385 nm.

According to the method of the present invention, even when the emission wavelength of light emitted from the active layer is in such a short wavelength region, the n-type nitride semiconductor layer formed thereon can be formed of a thick film of AlGaN having high Al proportion, so that an element exhibiting high light extraction efficiency can be produced.

The method for producing a semiconductor light-emitting element of the present invention may comprise, in addition to the steps (a) to (f),
a step (g) of etching the protective layer to expose the n-type nitride semiconductor layer; and
a step (h) of forming an n-side electrode on a top face of the exposed n-type nitride semiconductor layer, after the step (f).

According to the above method, it is possible to form an ohmic contact between the electrode and the n-type nitride semiconductor layer even when the protective layer is formed of an undoped nitride semiconductor.

Here, in the step (g), the whole of the protective layer may be etched, or at least the protective layer located in the region where the n-side electrode is to be formed may be etched.

When the protective layer is formed of an n-type nitride semiconductor (including the case where it is formed of the same material as that of the n-type nitride semiconductor layer), an ohmic contact can be formed by directly forming an electrode on the surface of the protective layer when the concentration of n-type impurity for doping the protective layer is high. When the impurity concentration is low, the electrode may be formed by executing the steps (g) and (h) in a similar manner to the case where the protective layer is formed of an undoped nitride semiconductor.

The present invention also provides a semiconductor light-emitting element comprising:
an n-type nitride semiconductor layer;
a p-type nitride semiconductor layer; and
an active layer sandwiched between the n-type nitride semiconductor layer and the p-type nitride semiconductor layer, wherein
the n-type nitride semiconductor layer includes AlₙGa₁₋ₙN (0.05≦n≦0.08) having a thickness of more than 2 μm.

Further, the n-type nitride semiconductor layer may include AlₙGa₁₋ₙN (0.05≦n≦0.07) having a thickness of equal to or more than 3 μm.

According to such configuration, since the n-type nitride semiconductor layer is formed of a thick film of AlGaN, extension of the current in the direction parallel with the substrate plane is ensured, and a light-emitting element having high light extraction efficiency is realized. Further, since such a crack-free thick film of AlGaN can be formed by the above production method, the conventional problem of deterioration in luminous efficiency caused by the presence of a defect is greatly mitigated.

### Effect of the Invention

According to the present invention, even when the n-type nitride semiconductor layer is formed of a material having high band gap energy, it is possible to form a thick film while holding the defect density down. Accordingly, it is possible to realize a light-emitting element having high extraction efficiency even for emitting light in an short wavelength region such as near-ultraviolet region.

### BRIEF DESCRIPTION OF THE DRAWINGS

FIG. 1 is a sectional view schematically showing a structure of a first embodiment of the semiconductor light-emitting element of the present invention;

FIG. 2A is a part of a production process of the first embodiment of the semiconductor light-emitting element;

FIG. 2B is a part of a production process of the first embodiment of the semiconductor light-emitting element;

FIG. 2C is a sectional view schematically showing a configuration of a multi-layered film 5;

FIG. 2D is a part of a production process of the first embodiment of the semiconductor light-emitting element;

FIG. 2E is a part of a production process of the first embodiment of the semiconductor light-emitting element;

FIG. 2F is a part of a production process of the first embodiment of the semiconductor light-emitting element;

FIG. 2G is a part of a production process of the first embodiment of the semiconductor light-emitting element;

FIG. 2H is a part of a production process of the first embodiment of the semiconductor light-emitting element;

FIG. 21 is a part of a production process of the first embodiment of the semiconductor light-emitting element;

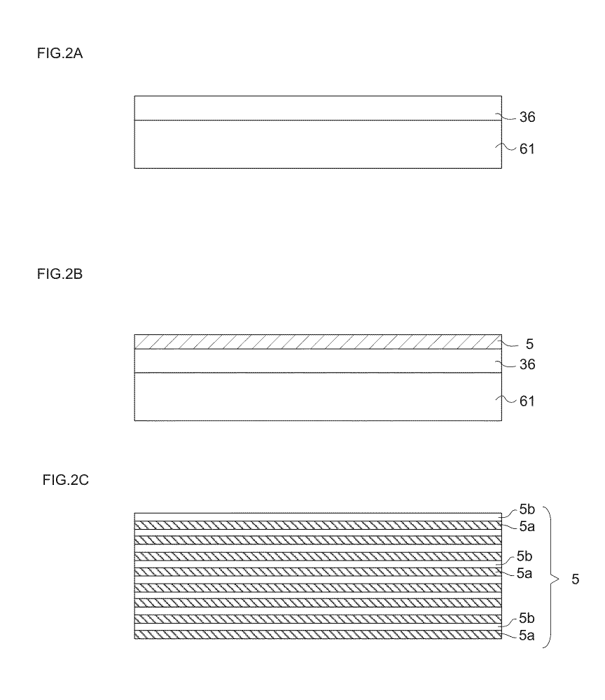

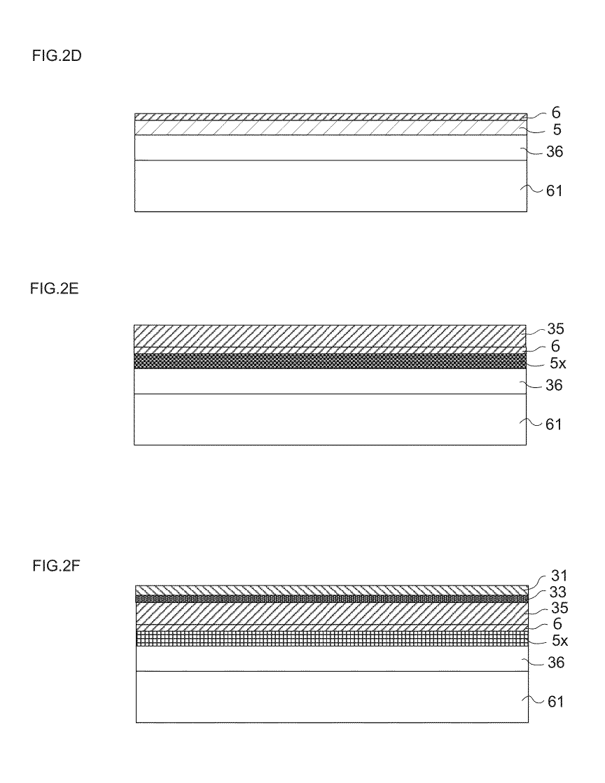

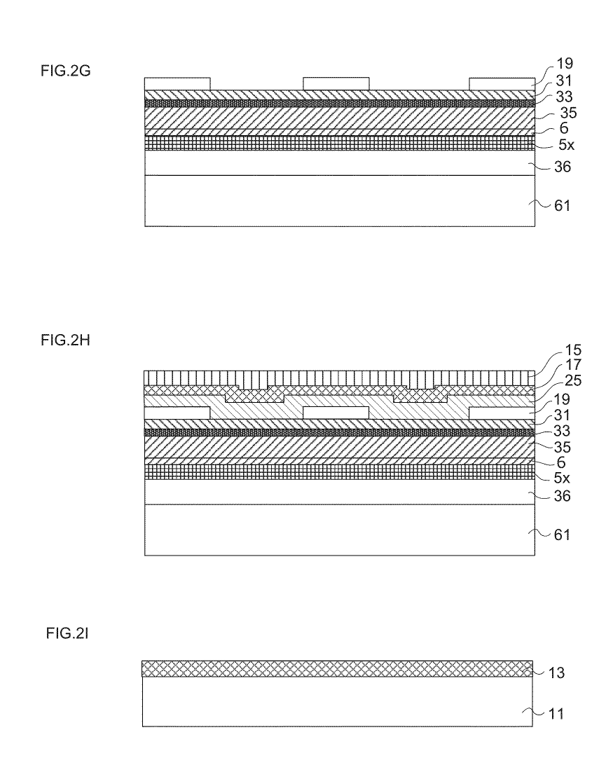

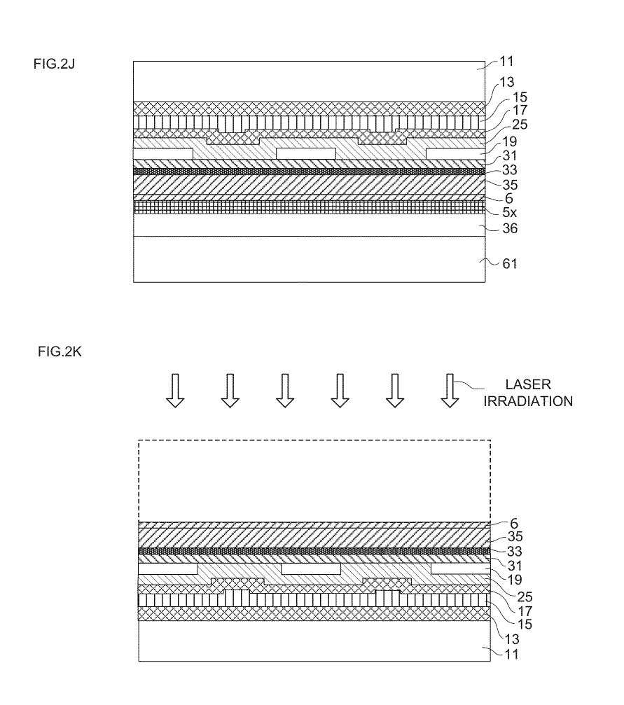

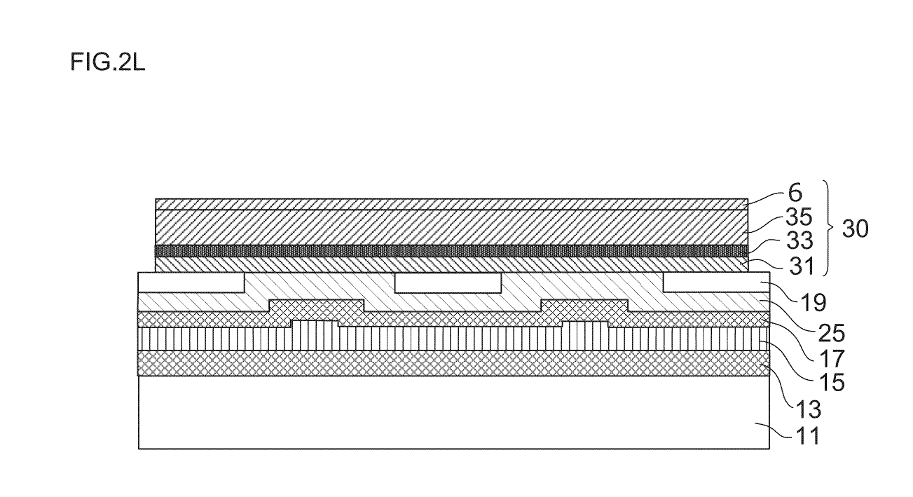

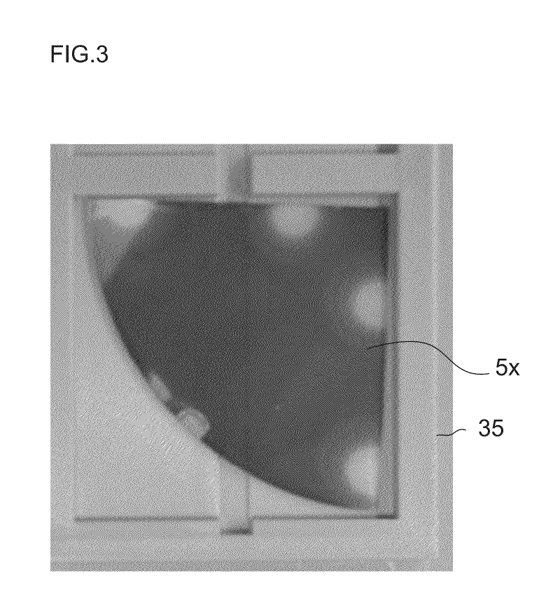

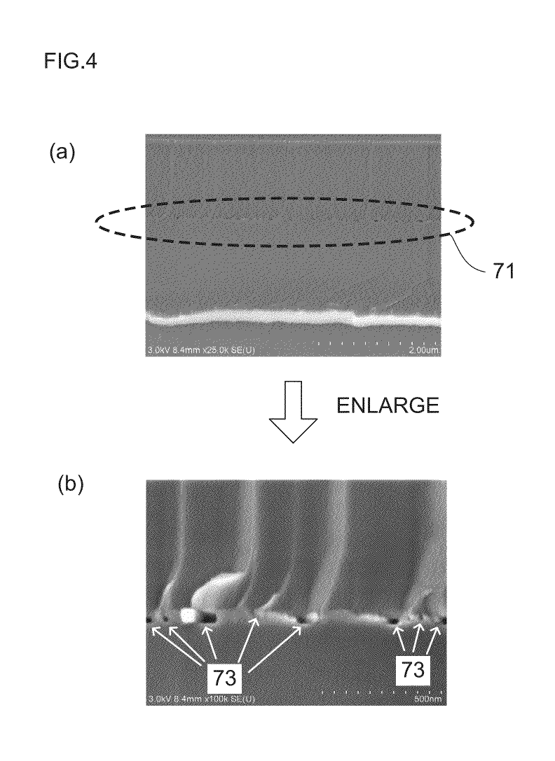

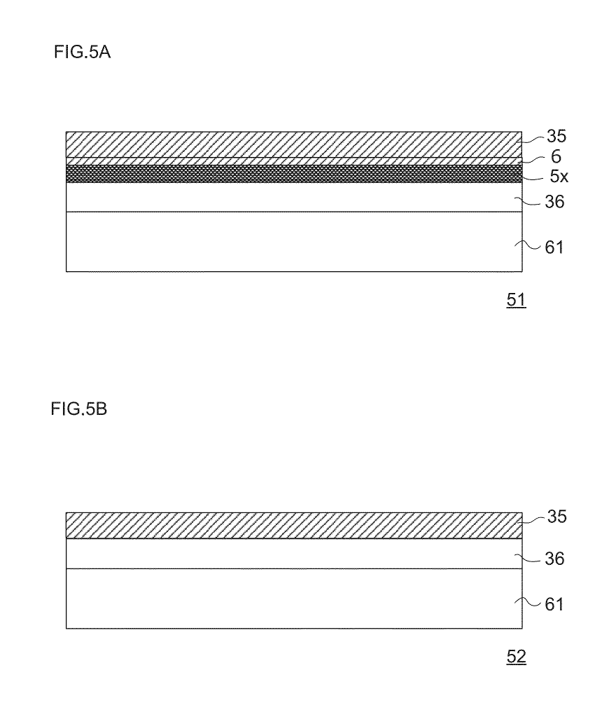

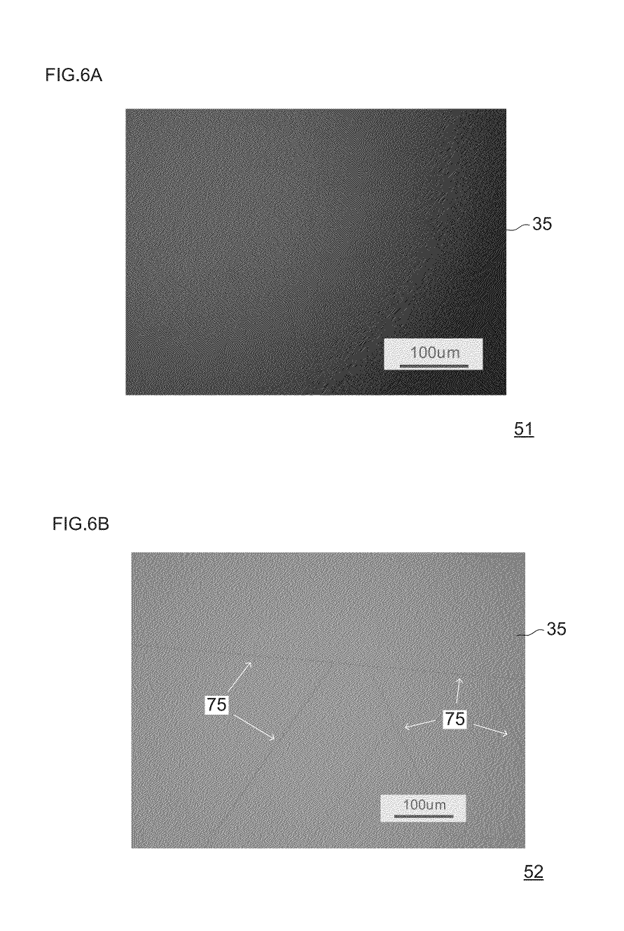

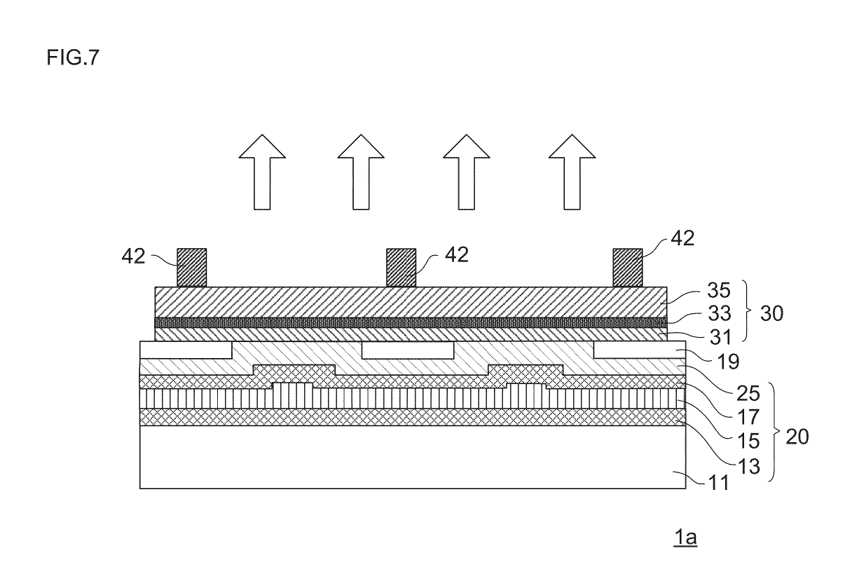

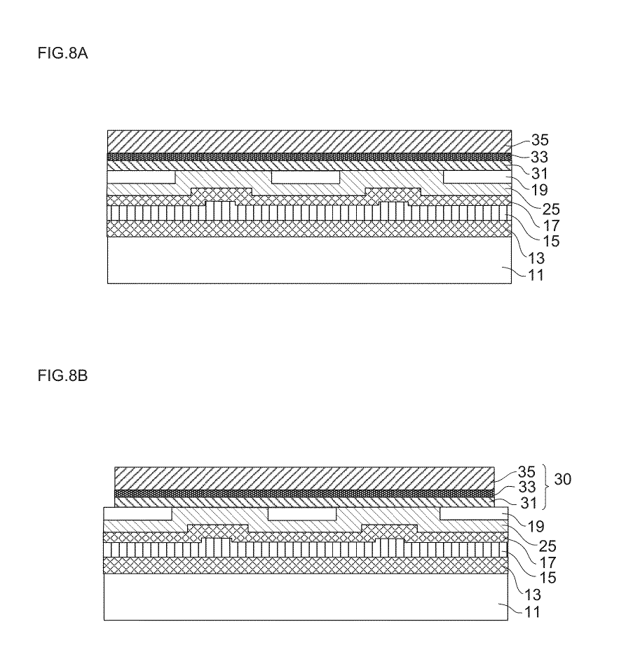

FIG. 2J is a part of a production process of the first embodiment of the semiconductor light-emitting element;

FIG. 2K is a part of a production process of the first embodiment of the semiconductor light-emitting element;

FIG. 2L is a part of a production process of the first embodiment of the semiconductor light-emitting element;

FIG. 3 is a micrograph showing the state of the surface of the element after execution of step S4;

FIG. 4 is a section SEM micrograph of the region where the multi-layered film 5 has been formed and the vicinity thereof in the element after execution of step S4;

FIG. 5A is a sectional view schematically showing a configuration of an element for validation corresponding to working examples;

FIG. 5B is a sectional view schematically showing a configuration of an element for validation corresponding to working examples;

FIG. 6A is a DIC micrograph of the top face of the element for validation shown in FIG. 5A;

FIG. 6B is a DIC micrograph of the top face of the element for validation shown in FIG. 5B;

FIG. 7 is a sectional view schematically showing a structure of a second embodiment of the semiconductor light-emitting element of the present invention;

FIG. 8A is a part of a production process of the second embodiment of the semiconductor light-emitting element;

FIG. 8B is a part of a production process of the second embodiment of the semiconductor light-emitting element; and

FIG. 9 is a sectional view schematically showing a structure of a conventional semiconductor light-emitting element.

### DETAILED DESCRIPTION OF THE INVENTION

After describing one embodiment of a structure of the semiconductor light-emitting element of the present invention with reference to attached drawings, the production method therefor will be specifically described.

In each of the following drawings, the dimensional ratio in the drawing and the actual dimensional ratio do not necessarily coincide with each other. The description “AlGaN” is synonymous with the description AlₙGa₁₋ₙN (0<m<1), and simply means the composition ratio between Al and Ga for short, and does not intend to limit to the case where the composition ratio between Al and Ga is 1:1. The same also applies to the description “InGaN”. In this description, “a layer A formed on another layer B” means a condition where the layer A is formed directly or through a thin film on the layer B, and does not intend to limit to the former condition.

### First Embodiment

In the following, a first embodiment of the semiconductor light-emitting element of the present invention will be described.

### [Structure]

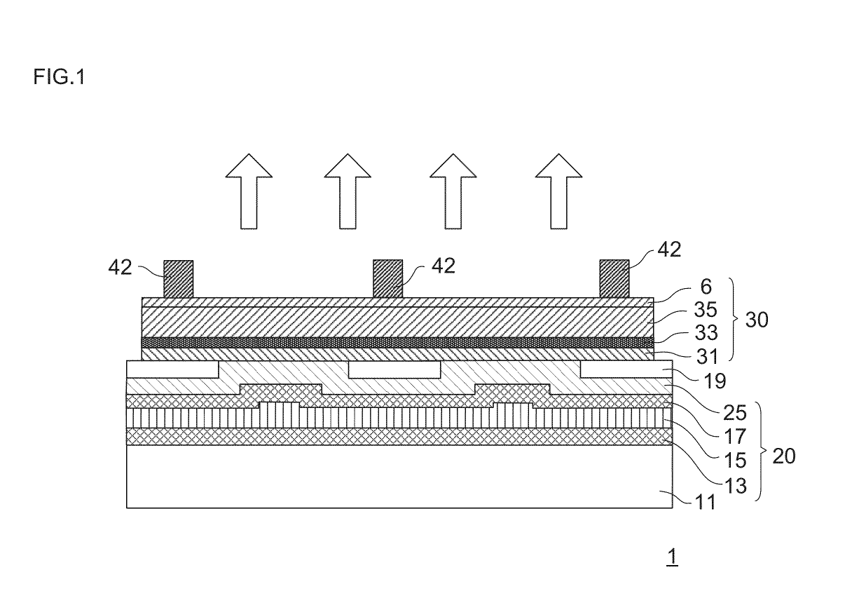

FIG. 1 is a sectional view schematically showing a structure of a first embodiment of the semiconductor light-emitting element of the present invention. A semiconductor light-emitting element 1 is made up of an n-type nitride semiconductor layer 35, a p-type nitride semiconductor layer 31 and an active layer 33 sandwiched therebetween. The same constituent as that in the conventional semiconductor light-emitting element 90 shown in FIG. 9 is denoted by the same reference numeral.

In the semiconductor light-emitting element 1 of the embodiment shown in FIG. 1, a conductive layer 20 is formed on a substrate 11, a semiconductor layer 30 is formed on the conductive layer 20, and an n-side electrode 42 is formed on the semiconductor layer 30. The semiconductor layer 30 has a p-type nitride semiconductor layer 31, an active layer 33, an n-type nitride semiconductor layer 35, and a protective layer 6. In the present embodiment, description will be made for the case where the protective layer 6 is formed of the same material as that of the n-type nitride semiconductor layer 35 (namely, n-type nitride semiconductor). As will be later described in the description of the production method, the protective layer 6 and the n-type nitride semiconductor layer 35 differ from each other in growth temperature.

Unlike the semiconductor layer 95 provided in the conventional semiconductor light-emitting element 90 shown in FIG. 9, the n-type nitride semiconductor layer 35 is formed of an AlGaN layer having a thickness of more than 2 μm, and is more preferably formed of an AlGaN layer having a thickness of equal to or more than 3 μm. According to the later-described production method, even when the n-type nitride semiconductor layer 35 is formed as a thick film as described above, it is possible to form a highly accurate semiconductor layer having no or almost no crack. The term “crack free” used herein includes not only the case perfectly lacking a crack in the semiconductor layer, but also the case where almost no crack is included in the semiconductor layer (for example, the state that the number of cracks included in a semiconductor layer of a 1 cm cube is not more than one).

Hereinafter, each constituent included in the nitride semiconductor layer 1 shown in FIG. 1 will be described.

### (Substrate 11)

The substrate 11 is formed of a conductive substrate of, for example, CuW, W, or Mo, or a semiconductor substrate of Si or the like.

### (Conductive Layer 20)

On the substrate 11, the conductive layer 20 having a multi-layered structure is formed. In the present embodiment, the conductive layer 20 includes a solder diffusion preventing layer 13, a solder layer 15, a solder diffusion preventing layer 17 and a metal electrode 25.

The solder layer 15 is formed of, for example, Au-Sn, Au-In, Au-Cu-Sn, Cu-Sn, Pd-Sn, or Sn. In bonding the substrate 11 with another substrate (growth substrate 61 as will be described later), the solder layer 15 functions as a layer for ensuring the adhesion of both substrates.

The solder diffusion preventing layer 17 is formed of, for example, Pt-based metal (alloy of Ti and Pt), W, Mo, or Ni. As will be described later, the solder diffusion preventing layer 17 performs a function of preventing deterioration in luminous efficiency due to decrease in the reflectance in the metal electrode 25 as a result of that the material constituting the solder layer 15 diffuses toward the metal electrode 25 in bonding via the solder layer 15. Also, the solder diffusion preventing layer 13 is formed for the purpose of preventing the material constituting the solder layer 15 from diffusing toward the substrate 11, and is formed of, for example, the same material as the solder diffusion preventing layer 17. From the viewpoint of preventing the material of the solder layer 15 from diffusing toward the metal electrode 25, the solder diffusion preventing layer 13 may not be provided.

The metal electrode 25 is formed of, for example, Ag (including Ag alloy), Al, or Rh. In the semiconductor light-emitting element 1, it is assumed that light emitted from the active layer 33 of the semiconductor layer 30 is extracted in the upward direction of FIG. 1 (on the side of the n-side electrode 42). The metal electrode 25 has a function as a reflective electrode for reflecting light emitted downward from the active layer 33 upwardly to enhance the luminous efficiency.

The conductive layer 20 is partly in contact with the semiconductor layer 30, and when a voltage is applied between the substrate 11 and the n-side electrode 42, a current pathway passing through the substrate 11, the conductive layer 20, the semiconductor layer 30 and the n-side electrode 42 is established.

### (Insulating Layer 19)

The insulating layer 19 is formed of, for example, SiO₂, SiN, Zr₂O₃, AlN, or Al₂O₃. In the insulating layer 19, the top face is in contact with the semiconductor layer 30, more specifically, with the bottom face of the p-type nitride semiconductor layer 31. The insulating layer 19 has a function as an etching stopper layer at the time of separating the element (later-described step S12) as will be described later, and also has a function of extending the current in the direction parallel with the plane of the substrate 11.

### (Semiconductor Layer 30)

As described above, the semiconductor layer 30 includes the p-type nitride semiconductor layer 31, the active layer 33, the n-type nitride semiconductor layer 35, and the protective layer 6.

The p-type nitride semiconductor layer 31 is formed of, for example, GaN or AlGaN, and is doped with a p-type impurity such as Mg, Be, Zn, or C.

The active layer 33 is formed of a semiconductor layer having such a structure that, for example, a light-emitting layer comprising InGaN and a barrier layer comprising AlGaN are repeatedly laminated. These layers may be undoped or doped into p-type or n-type.

The n-type nitride semiconductor layer 35 is formed of an n-type AlGaN layer having a thickness of larger than 2 μm as described above, and is doped with an n-type impurity such as Si, Ge, S, Se, Sn, or Te.

In the present embodiment, likewise the n-type nitride semiconductor layer 35, the protective layer 6 is formed of an n-type AlGaN layer, and is doped with an n-type impurity such as Si, Ge, S, Se, Sn, or Te. The thickness of the protective layer 6 can be, for example, about 30 nm.

(n-Side Electrode 42)

In the present embodiment, the n-side electrode 42 is formed in a partial region on the top face of the protective layer 6, and is formed of Cr-Au, for example. In the structure of FIG. 1, the n-side electrode 42 is formed vertically above the insulating layer 19. Accordingly, the insulating layer 19 having low conductivity is formed below the n-side electrode 42, so that it is possible to obtain the effect of extending the current flowing in the active layer 33 in the horizontal direction.

The n-side electrode 42 is connected with a bonding wire (not shown) formed of, for example, Au or Cu, and the other end of the wire is connected, for example, with a feed pattern (not shown) on the substrate 11.

### [Production Method]

Successively referring to FIG. 2A to FIG. 2L, one example of a method for producing the semiconductor light-emitting element 1 shown in FIG. 1 will be described. The production conditions and dimensions such as thickness described hereinafter are given merely for exemplification, and the present invention will not be limited by these numerical values.

By employing the production method as will be described below, it is possible to realize a highly accurate semiconductor layer having no or almost no crack even when the n-type nitride semiconductor layer 35 is formed into an AlGaN layer having a thickness of more than 2 μm, more preferably an AlGaN layer having a thickness of equal to or more than 3 μm.

### (Step S1)

As shown in FIG. 2A, an undoped GaN layer 36 is formed on the growth substrate 61 by epitaxial growth.

As the growth substrate 61, a c-plane sapphire substrate is prepared, and the substrate is subjected to cleaning. More concretely, the cleaning is conducted by placing the growth substrate 61 (c-plane sapphire substrate) in a treatment furnace of, for example, a MOCVD (Metal Organic Chemical Vapor Deposition) device, and elevating the temperature in the furnace to 1150° C. under the flow of hydrogen gas at a flow rate of 10 slm in the treatment furnace.

Then, on the surface of the growth substrate 61, a low-temperature buffer layer comprising GaN is formed, and further a foundation layer comprising GaN is formed thereon, and thus the GaN layer 36 is formed. A more concrete method for forming the GaN layer 36 is, for example, as follows.

First, the pressure and the temperature in the furnace of the MOCVD device are set at 100 kPa and 480° C., respectively. Then trimethylgallium (TMG) at a flow rate of 50 μmol/minute and ammonia at a flow rate of 250000 μmol/minute are supplied as a source gas into the treatment furnace for 68 seconds under the flow of nitrogen gas and hydrogen gas each at a flow rate of 5 slm as a carrier gas in the treatment furnace. As a result, a low-temperature buffer layer comprising GaN having a thickness of 20 nm is formed on the surface of the growth substrate 61.

Then, the temperature in the furnace of the MOCVD device is elevated to 1050° C. Then, TMG at a flow rate of 100 μmol/minute and ammonia at a flow rate of 250000 μmol/minute are supplied as a source gas into the treatment furnace for 60 minutes under the flow of nitrogen gas at a flow rate of 20 slm and hydrogen gas at a flow rate of 15 slm as a carrier gas in the treatment furnace. As a result, a foundation layer comprising GaN having a thickness of about 3 μm is formed on the surface of the low-temperature buffer layer. The low-temperature buffer layer and the foundation layer form the GaN layer 36.

As the growth substrate 61, a GaN substrate may be used. Also in this case, likewise the case of the sapphire substrate, after execution of cleaning of the surface in the MOCVD device, the temperature in the furnace of the MOCVD device is set at 1050° C., and TMG at a flow rate of 100 μmol/minute and ammonia at a flow rate of 250000 μmol/minute are supplied as a source gas into the treatment furnace for 10 minutes under the flow of nitrogen gas at a flow rate of 20 slm and hydrogen gas at a flow rate of 15 slm as a carrier gas in the treatment furnace. As a result, the GaN layer 36 having a thickness of about 500 nm is formed on the surface of the GaN substrate.

Step S1 corresponds to step (a).

### (Step S2)

As shown in FIG. 2B, the multi-layered film 5 is formed on the GaN layer 36. As shown in FIG. 2C, the multi-layered film 5 is formed, for example, by laminating an InGaN layer 5a having a thickness of 3 nm and a GaN layer 5b having a thickness of 2.5 nm in 8 periods. Here, as the InGaN layer 5a, In_{0.15}Ga_{0.85}N is formed.

The number of periods of the InGaN layer 5a and the GaN layer 5b constituting the multi-layered film 5 is not limited to 8. The multi-layered film 5 may be formed by a superlattice layer of InGaN/GaN.

More specifically, for example, the following forming method is employed. First, the temperature in the furnace of the MOCVD device is lowered to about 750° C. Then, the step of supplying TMG at a flow rate of 10 μmol/minute, trimethylindium (TMI) at a flow rate of 12 μmol/minute and ammonia at a flow rate of 300000 μmol/minute into the treatment furnace as a source gas for 60 seconds under the flow of nitrogen gas at a flow rate of 15 slm and hydrogen gas at a flow rate of 1 slm as a carrier gas in the treatment furnace is conducted. Then, the step of supplying TMG at a flow rate of 10 μmol/minute and ammonia at a flow rate of 300000 μmol/minute into the treatment furnace for 72 seconds is conducted. Thereafter, by repeating these two steps, the multi-layered film 5 made up of 8 periods of In_{0.15}Ga_{0.85} having a thickness of 2.5 nm and GaN having a thickness of 3 nm is formed on the GaN layer 36.

Since In can be taken into crystals only at lower temperature in comparison with Ga or Al, the growth temperature in step S2 is set lower than in step S1. Since there is a difference in lattice constant between InGaN and GaN, when the InGaN layer 5a is solely formed as a thick film, a defect occurs in the InGaN layer 5a due to the thickness exceeding the critical thickness. Such a defect is undesired because it is taken over to each semiconductor layer formed thereon, and causes deterioration in luminous efficiency.

As will be described later, the multi-layered film 5 formed in step S2 is thermally decomposed during execution of the subsequent step S4, and as a result, metal such as In or Ga precipitates in that region. At this time, the volume contracts in association with breakage of crystals and precipitation of metal, and thus a void (bore part) is formed in that region. For forming the n-type nitride semiconductor layer 35 as a crack-free thick film, equal to or more than a predetermined quantity of voids needs to be formed. In other words, even if the InGaN layer 5a is solely formed to have a small thickness, a crack can occur when the n-type nitride semiconductor layer 35 is formed as a thick film because a sufficient quantity of voids is not formed in step S4.

In light of the above, the thickness of the InGaN layer 5a and the number of periods of the multi-layered film are appropriately set so that a sufficient quantity of voids can be generated in step S4, and the crack-free InGaN layer 5a can be formed. Also in step S2, the multi-layered film 5 should include at least a nitride semiconductor layer containing In and a different nitride semiconductor layer. As the nitride semiconductor layer containing In, an AlGaInN layer may be employed. In this case, the Al composition of the AlGaInN layer is preferably within 5%. The reason is as follows.

That is, assuming the case where the Al composition of the AlGaInN layer as one layer constituting the multi-layered film 5 is set high, it is necessary to increase the In composition to generate a sufficient quantity of voids in the multi-layered film 5 in step S4. However, since the lattice constant of a-axis of InN is farther from that of GaN than AlN, cracking is more likely to occur in the layer when the In composition of the AlGaInN layer is increased. That is, it becomes difficult to deposit a crack-free AlGaInN layer capable of generating a sufficient quantity of voids in step S4.

Step S2 corresponds to step (b). The InGaN layer 5a corresponds to the “first layer”, and the GaN layer 5b corresponds to the “second layer”.

### (Step S3)

As shown in FIG. 2D, the protective layer 6 is formed on the multi-layered film 5.

Concretely, for example, the temperature in the furnace is set at about 900° C. which is higher than that in step S2 and lower than the temperature in forming the n-type nitride semiconductor layer 35 in the next step S4. Then, TMG at a flow rate of 10 μmol/minute, trimethylaluminum (TMA) at a flow rate of 1.6 μmol/minute, ammonia at a flow rate of 300000 μmol/minute and tetraethylsilane at a flow rate of 0.003 μmol/minute are supplied as a source gas into the treatment furnace for 12 minutes under the flow of nitrogen gas at a flow rate of 15 slm and hydrogen gas at a flow rate of 1 slm as a carrier gas in the treatment furnace.

As a result, the protective layer 6 having, for example, a composition of Al_{0.06}Ga_{0.94}N, a Si concentration of 5×10¹⁹/cm³, and a thickness of 30 nm is formed on the multi-layered film 5.

In step S3, since the thickness of AlGaN formed as the protective layer 6 is as small as about 30 nm, the tensile stress to the AlGaN layer is not so large, and a crack does not occur. Further, crystal growth with taking over the crystallinity of the underlying multi-layered film 5 formed of InGaN/GaN makes it possible to form the protective layer 6 having excellent crystallinity.

The protective layer 6 formed in step S3 may be formed of GaN without limited to AlGaN.

Step S3 corresponds to step (c).

(Step S4)

As shown in FIG. 2E, on the protective layer 6 formed in step S3, the n-type nitride semiconductor layer 35 formed of an n-type AlGaN layer having a thickness of larger than 2 μm is formed.

More specifically, for example, the temperature in the furnace of the MOCVD device is elevated to about 1050° C. which is higher than that in step S3, and TMG at a flow rate of 94 μmol/minute, TMA at a flow rate of 6 μmol/minute, ammonia at a flow rate of 250000 μmol/minute and tetraethylsilane at a flow rate of 0.03 μmol/minute are supplied as a source gas into the treatment furnace for 60 minutes under the flow of nitrogen gas at a flow rate of 20 slm and hydrogen gas at a flow rate of 15 slm as a carrier gas in the treatment furnace.

As a result, the n-type nitride semiconductor layer 35 having, for example, a composition of Al_{0.06}Ga_{0.94}N, a Si concentration of 5×10¹⁹/cm³, and a thickness of 3 μm is formed on the protective layer 6.

In step S4, the temperature in the furnace is as high as about 1050° C. during formation of the n-type nitride semiconductor layer 35. In this condition, the multi-layered film 5 formed in step S2 is thermally decomposed and the crystallinity is broken (layer 5x in FIG. 2E), and In and Ga precipitate which have constituted InGaN. At this time, the volume contracts, and as a result, a void (bore part) arises in the region where the multi-layered film 5 has been originally formed.

FIG. 3 is a micrograph showing the state of the element surface after execution of step S4, and is a micrograph taken from above the n-type nitride semiconductor layer 35 shown in FIG. 2E with a differential interference contrast microscope (DIC). The blackish parts in the image are metal components of In, Ga and so on, and it is seen that formation of the layer 5x in which crystallinity is broken and metal precipitates can be observed.

Here, the case is assumed where step S3 is not conducted, namely, the protective layer 6 is not formed, and the n-type nitride semiconductor layer 35 is formed directly on the multi-layered film 5. After forming the multi-layered film 5, the temperature in the furnace is elevated to about 1050° C. and a source gas is supplied in order to form the n-type nitride semiconductor layer 35. As a result of placing the multi-layered film 5 under such high temperature, the multi-layered film 5 is thermally decomposed and crystallinity is broken as described above. In this case, the n-type nitride semiconductor layer 35 cannot grow with taking over the crystallinity of the underlying layer. In particular, since it is required to expose to the high-temperature environment for a certain time or longer to form the n-type nitride semiconductor layer 35 as a thick film, the breakage of the crystallinity of the multi-layered film 5 is inevitable, and a layer having excellent crystallinity is difficult to be formed thereafter.

However, according to the present production method, the protective layer 6 is formed in step S3 directly before step S4. Therefore, even if the temperature in the furnace is elevated to high temperature to form the n-type nitride semiconductor layer 35, and the crystallinity of the multi-layered film 5 is broken as a result, it is possible to grow the n-type nitride semiconductor layer 35 with taking over the crystallinity of the protective layer 6. Therefore, the crystal property of the n-type nitride semiconductor layer 35 will not be degraded due to breakage of the crystallinity of the multi-layered film 5.

In the layer 5x that is formed as a result of thermal decomposition of the multi-layered film 5 placed under high temperature, metal such as In or Ga precipitates as described above, and voids are formed in association with the contraction due to thermal decomposition . FIG. 4 is a micrograph of a section of the element in the vicinity of the region where the multi-layered film 5 has been formed, namely, in the vicinity of the region where the layer 5x is formed, taken with an SEM (Scanning Electron Microscope) . FIG. 4(b) is an image enlarging a region 71 of FIG. 4(a).

As can be seen from FIG. 4(b), a large number of voids 73 are formed in the region where the layer 5x is formed. Also from FIG. 3 and FIG. 4, it can be seen that metal precipitates as a result of thermal decomposition of the multi-layered film 5, and the voids 73 are formed as a result of contraction of the volume during this process

Step S4 corresponds to step (d).

### (Step S5)

As shown in FIG. 2F, the active layer 33 is formed on the n-type nitride semiconductor layer 35, and the p-type nitride semiconductor layer 31 is formed on the active layer 33. One concrete example of the method of the formation is as follows.

First, the pressure and the temperature in the furnace of the MOCVD device are set at 100 kPa and 830° C., respectively. Then, the step of supplying TMG at a flow rate of 10 μmol/minute, TMI at a flow rate of 12 μmol/minute and ammonia at a flow rate of 300000 μmol/minute into the treatment furnace as a source gas for 48 seconds under the flow of nitrogen gas at a flow rate of 15 slm and hydrogen gas at a flow rate of 1 slm as a carrier gas in the treatment furnace is conducted. Then, the step of supplying TMG at a flow rate of 10 μmol/minute, TMA at a flow rate of 1.6 μmol/minute, tetraethylsilane at a flow rate of 0.002 μmol/minute and ammonia at a flow rate of 300000 μmol/minute into the treatment furnace for 120 seconds is conducted.

Thereafter, by repeating these two steps, the active layer 33 having a multiquantum well structure made up of 15 periods of a light-emitting layer comprising InGaN having a thickness of 2 nm and a barrier layer comprising n-type AlGaN having a thickness of 7 nm is formed on the n-type nitride semiconductor layer 35.

The pressure in the furnace of the MOCVD device is sequentially kept at 100 kPa, and the temperature in the furnace is elevated to 1025° C. under the flow of nitrogen gas at a flow rate of 15 slm and hydrogen gas at a flow rate of 25 slm as a carrier gas in the treatment furnace. Then, TMG at a flow rate of 35 μmol/minute, TMA at a flow rate of 20 μmol/minute, ammonia at a flow rate of 250000 μmol/minute and bis (cyclopentadienyl)magnesium (Cp₂Mg) at a flow rate of 0.1 μmol/minute for doping with a p-type impurity are supplied into the treatment furnace as a source gas for 60 seconds. As a result, a hole supply layer having a thickness of 20 nm and a composition of Al_{0.3}Ga_{0.7}N is formed on the surface of the active layer 33. Then, the source gas is supplied for 360 seconds after changing the flow rate of TMA to 4 μmol/minute to form a hole supply layer having a thickness of 120 nm and a composition of Al_{0.13}Ga_{0.87}N. These hole supply layers form the p-type nitride semiconductor layer 31 . The concentration of the p-type impurity in the p-type nitride semiconductor layer 31 is, for example, about 3×10¹⁹/cm³.

Thereafter, by supplying the source gas for 20 seconds after stopping supplying TMA and changing the flow rate of Cp₂Mg to 0.2 μmol/minute, a p-type contact layer having a thickness of about 5 nm and a p-type impurity concentration of about 1×10²⁰/cm³ may be formed. In this case, the p-type nitride semiconductor layer 31 includes also this p-type contact layer.

Step S5 corresponds to step (e).

### (Step S6)

The wafer formed by the steps up to step S5 is subjected to an activation treatment. More concretely, for example, an activation treatment is conducted at 650° C. for 15 minutes in a nitrogen atmosphere by using a RTA (Rapid Thermal Anneal) device.

### (Step S7)

As shown in FIG. 2G, the insulating layer 19 is formed in a predetermined region on the top face of the p-type nitride semiconductor layer 31.

More specifically, for example, on the top face of the p-type nitride semiconductor layer 31 in the region which is to be a boundary with the adjacent element, SiO₂ is deposited into a thickness of about 200 nm by sputtering to form the insulating layer 19. The material to be deposited should be an insulating material, and may be SiN or Al₂O₃, for example. At this time, the region where the insulating layer 19 is not formed may be masked.

### (Step S8)

As shown in FIG. 2H, the metal electrode 25 is formed to cover the top faces of the p-type nitride semiconductor layer 31 and the insulating layer 19. Further, on the top face of the metal electrode 25, the solder diffusion preventing layer 17 is formed, and on the top face of the solder diffusion preventing layer 17, the solder layer 15 is formed. A concrete method of the formation is, for example, as follows.

First, Ni having a thickness of 0.7 nm and Ag having a thickness of 120 nm are deposited on the whole surface so as to cover the top faces of the p-type nitride semiconductor layer 31 and the insulating layer 19 by means of a sputtering device, so that the metal electrode 25 is formed. Then, contact annealing is conducted at 400° C. for 2 minutes in dry air or inert gas atmosphere by using the RTA device.

Then, on the top face (Ag surface) of the metal electrode 25, three periods of Ti having a thickness of 100 nm and Pt having a thickness of 200 nm are deposited by an electron-beam vapor deposition device (EB device) to form the solder diffusion preventing layer 17. Then, on the top face (Pt surface) of the solder diffusion preventing layer 17, Ti having a thickness of 10 nm is vapor deposited, and then an Au-Sn solder composed of 80% Au and 20% Sn is vapor deposited in a thickness of 3 μm to form the solder layer 15.

### (Step S9)

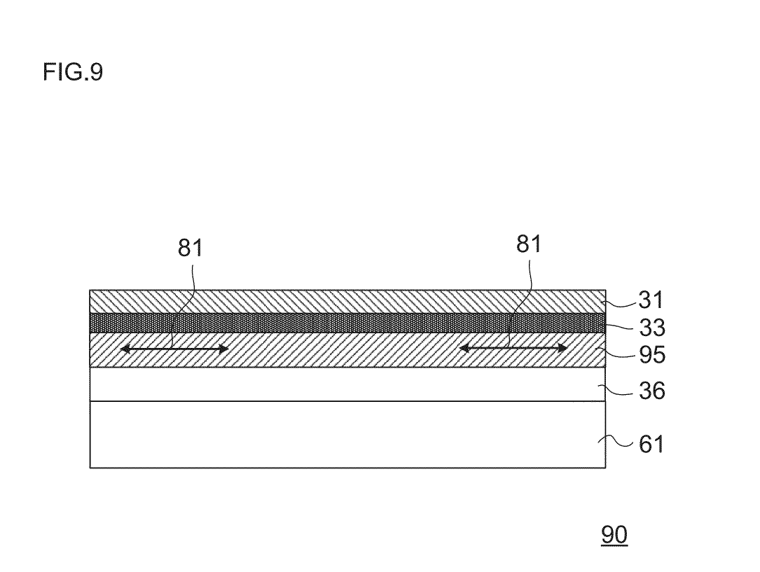

As shown in FIG. 21, on the substrate 11 that is prepared separately from the growth substrate 61, the solder diffusion preventing layer 13 is formed in a similar manner to that for the solder diffusion preventing layer 17 described above. As the substrate 11, a conductive substrate of CuW, W, Mo or the like, or a semiconductor substrate of Si or the like can be employed as described above.

### (Step S10)

As shown in FIG. 2J, the growth substrate 61 and the substrate 11 are bonded together. In one example, the solder layer 15 formed on the growth substrate 61 and the solder diffusion preventing layer 17 formed on the substrate 11 are bonded together at a temperature of 280° C. under a pressure of 0.2 MPa.

In the substrate 11, the solder layer 15 may be formed also on the solder diffusion preventing layer 13, and the solder layer 15 on the substrate 11 and the solder layer 15 on the growth substrate 61 may be bonded together.

### (Step S11)

As shown in FIG. 2K, a laser beam is irradiated from the side of the growth substrate 61 to delaminate the growth substrate 61. Concretely, for example, a double wave laser beam (wavelength 532 nm) of YAG laser (Nd: YAG laser) is irradiated from the side of the growth substrate 61 in the state that the growth substrate 61 faces upward and the substrate 11 faces downward.

The laser beam irradiated at this time is light having a wavelength of smaller energy than the band gap energy of the nitride semiconductor constituting the layer 5x, namely the multi-layered film 5. Since the layer 5x in which metal such as In precipitates as a result of thermal decomposition of the multi-layered film 5 is formed through step S4, even with the light having a wavelength of such small energy, the light is absorbed by metal in the layer 5x, and the growth substrate 61 can be delaminated. Further, the laser beam is preferably light having a wavelength of smaller energy than the band gap energy of the material forming the growth substrate 61 and the GaN layer 36. As a result, the laser beam passes through the growth substrate 61 and the GaN layer 36, and is absorbed in the layer 5x, resulting in temperature rise of the interface between the layer 5x and the protective layer 6. Accordingly, the layer 5x is detached from the protective layer 6 as a result of decomposition of the layer 5x, and the growth substrate 61 is delaminated from the substrate 11.

Then, the surface of the protective layer 6 is rinsed with acid such as aqua regia as necessary to remove the constituent materials (metal materials such as In and Ga) of the layer 5x remaining on the surface.

Step S11 corresponds to step (f).

### (Step S12)

As shown in FIG. 2L, the adjacent elements are separated from each other. Concretely, for example, for the boundary region between adjacent elements, the semiconductor layer 30 is etched by using an ICP device until the top face of the insulating layer 19 is exposed. At this time, the insulating layer 19 functions as an etching stopper as described above.

### (Step S13)

As shown in FIG. 1, the n-side electrode 42 is formed in a predetermined region of the top face of the protective layer 6, more specifically, in a part of the region vertically above the insulating layer 19. One exemplary method of forming the n-side electrode 42 includes vapor deposition of Cr having a thickness of 100 nm and Au having a thickness of 3 μm, followed by annealing at 250° C. for about 1 minute in a nitrogen atmosphere.

### (Step S14)

Then, the elements are separated from each other, for example, by using a laser dicing device, and the back face of the substrate 11 is joined with a package, for example, by an Ag paste. Further, in a partial region of the n-side electrode 42, the bonding wire is connected. For example, a bonding wire made of Au is connected with a bonding region of φ100 μm under a load of 50 g.

### [Verification]

Next, the following point will be verified: the crack-free n-type nitride semiconductor layer 35 can be realized even in the form of a thick film by the aforementioned production method.

Each of FIG. 5A and FIG. 5B represents a sectional view schematically showing a configuration of an element for validation. An element for validation 51 shown in FIG. 5A assumes the element produced through steps S1 to S4 described above, and corresponds to the element after execution of step S4 shown in FIG. 2E.

A method for producing the element for validation 51 will be described. First, on the growth substrate 61 formed of sapphire, the GaN layer 36 having a thickness of 3 μm was formed, and then on the GaN layer 36, the multi-layered film 5 including 8 periods of In_{0.15}Ga_{0.85}N having a thickness of 2.5 nm and GaN having a thickness of 3 nm was formed. Next, on the multi-layered film 5, the protective layer 6 formed of Al_{0.06}Ga_{0.94}N having a thickness of 30 nm was grown in the temperature condition of about 900° C. Next, on the protective layer 6, the n-type nitride semiconductor layer 35 formed of n-type Al_{0.06}Ga_{0.94}N having a thickness of 3.5 μm was grown under the temperature condition of about 1050° C. In the course of forming the n-type nitride semiconductor layer 35, the multi-layered film 5 was thermally decomposed, and the layer 5x was formed in the region where the multi-layered film 5 had been formed. The element for validation 51 corresponds to a working example.

An element for validation 52 is an element in which the n-type nitride semiconductor layer 35 is formed on the growth substrate 61 by a conventional method. A method for producing the element for validation 52 will be described. First, on the growth substrate 61 formed of sapphire, the GaN layer 36 having a thickness of 3 μm was formed, and then on the GaN layer 36, the n-type nitride semiconductor layer 35 formed of n-type Al_{0.06}Ga_{0.94}N having a thickness of 3.5 μm was grown under the temperature condition of about 1050° C. The element for validation 52 corresponds to a comparative example.

FIG. 6A is a micrograph of the top face of the element for validation 51 taken by DIC (differential interference contrast microscope). FIG. 6B is a micrograph of the top face of the element for validation 52 taken by DIC. According to these micrographs, many cracks 75 were observed in the element for validation 52, but no crack was observed in the element for validation 51.

As described in the section of “Problem to be solved by the invention”, since there is a significant difference in lattice constant between GaN and AlGaN, when the AlGaN layer is laminated as a thick film on the GaN layer, a large tensile stress arises in the AlGaN layer, and a crack caused by the same occurs. The micrograph of FIG. 6B obviously shows this fact.

On the other hand, according to the element for validation 51, a crack is not observed even when the n-type nitride semiconductor layer 35 having a thickness of as large as 3.5 μm is formed on the GaN layer 36. This is ascribable to the fact that owing to the formation of a large number of voids 73 in the layer 5x which is formed as a result of thermal decomposition of the multi-layered film 5 as already described with reference to FIG. 4, part of the stress is absorbed by these voids 73 and the critical thickness of the n-type nitride semiconductor layer 35 increases.

In step S2 descried above, 8 periods of the InGaN layer 5a and the GaN layer 5b were laminated to form the multi-layered film 5. This aims at forming the voids 73 capable of absorbing the stress arising in the n-type nitride semiconductor layer 35, and also aims at sufficiently absorbing the laser beam irradiated in step S11. In other words, when the total thickness of the InGaN layer 5a in the multi-layered film 5 is insufficient, In contained in the multi-layered film 5 (layer 5x) cannot sufficiently absorb the laser energy in step S11, so that decomposition of the protective layer 6 in the interface is insufficient, and there is a fear that the growth substrate 61 cannot be delaminated. Therefore, in forming the multi-layered film 5, it is preferable to laminate the InGaN layer 5a and the GaN layer 5b within the thickness that will not cause cracking and within the period number that will not cause cracking.

In the above embodiment, while the InGaN layer 5a constituting the multi-layered film 5 formed in step S2 has a composition of In_{0.15}Ga_{0.85}N, the In composition of the InGaN layer 5a is appropriately selected. However, if the In composition of the InGaN layer 5a is extremely high (for example, more than 0.3), the critical thickness is low and the total thickness of the InGaN layer 5a is small in forming the crack-free multi-layered film 5, so that the energy amount absorbed in the multi-layered film 5 (layer 5x) in step S11 is low. As a result, there is a fear that the layer 5x cannot be completely detached from the protective layer 6.

On the other hand, if the In composition of the InGaN layer 5a is set at extremely low (for example, less than 0.05), the critical thickness of the InGaN layer 5a rises; however, the amount of metal precipitating in the layer 5x formed as a result of thermal decomposition of the multi-layered film 5 in forming the n-type nitride semiconductor layer 35 in a high temperature condition in step S4 decreases . This means that the amount of the voids 73 associated with the contraction of the volume decreases. As a result, there is a fear that the amount of the voids 73 can be insufficient to absorb the stress arising in the n-type nitride semiconductor layer 35.

Therefore, the In composition of the InGaN layer 5a is preferably equal to or more than 0.05 and equal to or less than 0.3, and more preferably equal to or more than 0.1 and equal to or less than 0.2.

Also, in step S3, the protective layer 6 is formed at higher temperature than in step S2; however, if the temperature is too high, the multi-layered film 5 will be thermally decomposed in the course of forming the protective layer 6. For this reason, the growth temperature in step S3 is preferably higher than that in step S2 and within the range that the multi-layered film 5 will not be thermally decomposed. More specifically, when the growth temperature in step S2 is defined as Tb, and the growth temperature in step S3 is defined as Tc, Tb<Tc<Tb+150(° C.) is preferably satisfied.

### Second Embodiment

In the following, a second embodiment of the semiconductor light-emitting element of the present invention will be described. The part common to that in the first embodiment is noted, and description thereof will be omitted.

### [Structure]

FIG. 7 is a sectional view schematically showing a structure of a second embodiment of the semiconductor light-emitting element of the present invention. Comparing with the semiconductor light-emitting element 1 of the first embodiment, in a semiconductor light-emitting element la shown in FIG. 7, the protective layer 6 is not provided and the n-side electrode 42 is formed on the top face of the n-type nitride semiconductor layer 35. Other points are identical to those in the semiconductor light-emitting element 1 of the first embodiment.

### [Production Method]

In the following description of a method for producing the semiconductor light-emitting element la shown in FIG. 7, only the part different from that in the first embodiment will be described.

Steps S1 to S11 are executed in a similar manner to the first embodiment (see FIGS. 2A to FIG. 2K) . In the present embodiment, the protective layer 6 formed in step S3 may be formed of an undoped nitride semiconductor layer.

### (Step S11A)

As shown in FIG. 8A, the protective layer 6 is removed by wet etching using acid or by dry etching using an ICP device to expose the top face of the n-type nitride semiconductor layer 35. Step S11A corresponds to step (g).

### (Steps S12 to S14)

Subsequently, steps S12 to S14 are executed in a similar manner to the first embodiment. First, as shown in FIG. 8B, the adjacent elements are separated from each other by a method similar to the first embodiment. Thereafter, the n-side electrode 42 is formed on the top face of the n-type nitride semiconductor layer 25 in a similar manner to the first embodiment (corresponding to step (h)). Then, the elements are separated from each other, for example, with a laser dicing device, and the back face of the substrate 11 is joined with a package, for example, by an Ag paste. Further, a bonding wire is connected with a partial region of the n-side electrode 42.

According to the present embodiment, since the n-side electrode 42 can be brought into contact with the n-type nitride semiconductor layer 25, it is not necessary to form an ohmic contact between the protective layer 6 and the n-side electrode 42. Therefore, it is possible to form the protective layer 6 with an undoped semiconductor nitride layer. The method of the present embodiment can be employed also when the protective layer 6 is formed of the n-type semiconductor nitride layer.

In FIG. 8A, the protective layer 6 is completely removed in step S11A; however, only a partial region of the protective layer 6 including the region where the n-side electrode 42 is to be formed in S13 may be removed.

### Other Embodiments

Hereinafter, other embodiments will be described.

<1> In place of the insulating layer 19, a conductive oxide film layer may be formed. When the conductive oxide film layer is provided, the current is more likely to flow in the perpendicular direction in the semiconductor layer 30 because the conductivity is higher than that of the insulating layer 19; however, the effect of extending the current in the horizontal direction is realized because conductivity is much lower than that of ordinary conductive materials (metal or the like). As the conductive oxide film layer, for example, ITO, IZO, In₂O₃, SnO₂, IGZO (InGaZnOₓ) and the like can be used.

The insulating layer 19 and the conductive oxide film layer are preferably formed vertically (the direction orthogonal to the plane of the substrate 11) below the n-side electrode 42 in the meaning of extending the current in the horizontal direction; however, the present invention does not exclude the element lacking the insulating layer 19 and the conductive oxide film layer from the scope of the invention.

<2> The above structure and the production method are given as examples of embodiments, and not all of these configurations and processes are necessarily provided. For example, the solder layer 17 is formed to efficiently bond the growth substrate 61 and substrate 11 together, and is not necessarily required to achieve the function of the semiconductor light-emitting element 1 if the bonding of these two substrates can be achieved.

Further, the metal electrode 25 is preferably provided in the meaning of improving the light extraction efficiency by reflecting the light emitted from the active layer 33 toward the substrate 11 to the side of the n-side electrode 42; however it is not necessarily provided.

### DESCRIPTION OF THE REFERENCE NUMERALS

1, 1a: One embodiment of semiconductor light-emitting element of present invention

5: Multi-layered film

5a: InGaN layer

5b: GaN layer

5x: Layer formed as a result of thermal decomposition of multi-layered film

6: Protective layer

11: Substrate

13: Solder diffusion preventing layer

15: Solder layer

17: Solder diffusion preventing layer

19: Insulating layer

20: Conductive layer

25: Metal electrode

31: P-type nitride semiconductor layer

33: Active layer

35: N-type nitride semiconductor layer

36: GaN layer

42: N-side electrode

51: Element for validation (working example)

52: Element for validation (comparative example)

61: Growth substrate

71: Peripheral region of void

73: Void

75: Crack

81: Tensile stress

90: Conventional semiconductor light-emitting element

95: N-type nitride semiconductor layer

1. A method for producing a semiconductor light-emitting element, comprising:
a step (a) of forming a GaN layer on a growth substrate formed of a GaN substrate or a sapphire substrate;
a step (b) of forming a multi-layered film including a first layer formed of a nitride semiconductor containing In and a second layer formed of a nitride semiconductor having a composition different from that of the first layer on the GaN layer;
a step (c) of forming a protective layer formed of a nitride semiconductor on the multi-layered film;
a step (d) of forming an n-type nitride semiconductor layer at a growth temperature higher than that in the step (b) and the step (c) on the protective layer;
a step (e) of forming an active layer and a p-type nitride semiconductor layer on the n-type nitride semiconductor layer; and
a step (f) of irradiating light having a wavelength of smaller energy than band gap energy of the nitride semiconductor constituting the multi-layered film to delaminate the growth substrate, wherein
in the step (d), the multi-layered film is thermally decomposed to form an internal void.

2. The method for producing a semiconductor light-emitting element according to claim 1, wherein the multi-layered film is formed of a multi-layered film of InₓGa₁₋ₓN (0.1≦x≦0.2)/GaN.

3. The method for producing a semiconductor light-emitting element according to claim 1, wherein the n-type nitride semiconductor layer includes n-type AlₙGa₁₋ₙN (0≦n≦1) having a thickness of equal to or more than 2 μm.

4. The method for producing a semiconductor light-emitting element according to claim 1, wherein the protective layer is formed of the same material as that of the n-type nitride semiconductor layer.

5. The method for producing a semiconductor light-emitting element according to claim 1, wherein when the growth temperature in the step (b) is defined as Tb and the growth temperature in the step (c) is defined as Tc, Tb<Tc<Tb+150(° C.) is satisfied.

6. The method for producing a semiconductor light-emitting element according to claim 1, wherein the emission wavelength of the active layer is equal to or more than 362 nm and equal to or less than 385 nm.

7. The method for producing a semiconductor light-emitting element according to claim 1, wherein the method comprises after the step (f):
a step (g) of etching the protective layer to expose the n-type nitride semiconductor layer; and
a step (h) of forming an n-side electrode on a top face of the exposed n-type nitride semiconductor layer.

8. A semiconductor light-emitting element, comprising:
an n-type nitride semiconductor layer;
a p-type nitride semiconductor layer; and
an active layer sandwiched between the n-type nitride semiconductor layer and the p-type nitride semiconductor layer, wherein
the n-type nitride semiconductor layer includes AlₙGa₁₋ₙN (0.05≦n≦0.08) having a thickness of more than 2 μm.

9. The semiconductor light-emitting element according to claim 8, wherein the n-type nitride semiconductor layer includes AlₙGa₁₋ₙN (0.05≦n≦0.07) having a thickness of equal to or more than 3 μm.

10. The method for producing a semiconductor light-emitting element according to claim 2, wherein the n-type nitride semiconductor layer includes n-type AlₙGa₁₋ₙN (0≦n≦1) having a thickness of equal to or more than 2 μm.

11. The method for producing a semiconductor light-emitting element according to claim 2, wherein the protective layer is formed of the same material as that of the n-type nitride semiconductor layer.

12. The method for producing a semiconductor light-emitting element according to claim 3, wherein the protective layer is formed of the same material as that of the n-type nitride semiconductor layer.

13. The method for producing a semiconductor light-emitting element according to claim 10, wherein the protective layer is formed of the same material as that of the n-type nitride semiconductor layer.

14. The method for producing a semiconductor light-emitting element according to claim 2, wherein the emission wavelength of the active layer is equal to or more than 362 nm and equal to or less than 385 nm.

15. The method for producing a semiconductor light-emitting element according to claim 3, where in the emission wavelength of the active layer is equal to or more than 362 nm and equal to or less than 385 nm.

16. The method for producing a semiconductor light-emitting element according to claim 4, wherein the emission wavelength of the active layer is equal to or more than 362 nm and equal to or less than 385 nm.

17. The method for producing a semiconductor light-emitting element according to claim 10, wherein the emission wavelength of the active layer is equal to or more than 362 nm and equal to or less than 385 nm.

18. The method for producing a semiconductor light-emitting element according to claim 11, wherein the emission wavelength of the active layer is equal to or more than 362 nm and equal to or less than 385 nm.

19. The method for producing a semiconductor light-emitting element according to claim 12, wherein the emission wavelength of the active layer is equal to or more than 362 nm and equal to or less than 385 nm.

20. The method for producing a semiconductor light-emitting element according to claim 13, wherein the emission wavelength of the active layer is equal to or more than 362 nm and equal to or less than 385 nm.
